(19) United States
(12) Patent Application Publication
(10) Pub. No.: US 2007/0119616 A1
(43) Pub. Date: May 31, 2007

(54) Mounting substrate, manufacturing method of mounting substrate and manufacturing method of semiconductor device

(75) Inventors: Yasuyoshi Horikawa, Nagano (JP); Tomoo Yamasaki, Nagano (JP)

Correspondence Address: DRINKER BIDDLE & REATH (DC), 1500 K STREET, N.W., SUITE 1100, WASHINGTON, DC, 20005-1209, US

(73) Assignee: SHINKO ELECTRIC INDUSTRIES CO., LTD.

(21) Appl. No.: 11/605,316

(22) Filed: Nov. 29, 2006

(30) Foreign Application Priority Data
Nov. 30, 2005 (JP) P.2005-346095

(51) Int. Cl. H05K 1/00

(52) U.S. Cl. 174/250

(57) ABSTRACT

A mounting substrate for mounting a semiconductor chip, having a plurality of passive elements which are connected to the semiconductor chip and are formed to be mutually electrically-independent, and a wiring part including a plurality of via plugs respectively independently connected to the plurality of passive elements and pattern wiring connected to the via plugs, wherein the wiring part is constructed so that a state of connection between the semiconductor chip and the plurality of passive elements can be changed by changing the pattern wiring.

### TECHNICAL FIELD

The present disclosure relates to a mounting substrate which mounts a semiconductor chip and has a passive element connected to the semiconductor chip, and a semiconductor device made by mounting a semiconductor chip on the mounting substrate.

### RELATED ART

In recent years, various structures in which a passive element of a semiconductor chip is built into a semiconductor device with miniaturization and thinning of a semiconductor device (semiconductor package) for mounting a semiconductor chip have been proposed.

For example, one example of the passive element includes a thin film capacitor. The thin film capacitor is connected to a semiconductor chip and is used in various uses and may be used as, for example, a decoupling capacitor for stabilizing an action by suppressing variations in power source voltage of the semiconductor chip.

For example, FIGS. 10A to 10D show one example of a manufacturing method of a mounting substrate of a semiconductor chip into which a passive element is built by following a procedure.

First, in a step shown in FIG. 10A, a capacitor 12 made by forming a dielectric part 14 between a second electrode part 13 and a first electrode part 15 is formed on a substrate 11. In this case, an electrode pad 13A may be formed on the second electrode part 13 extending outside the dielectric part 14 and also an electrode pad 15A may be formed on the first electrode part 15. Further, an insulating layer 16 is formed so as to cover the capacitor 12 and a passive element substrate 10 made by installing the capacitor is formed.

Next, in a step shown in FIG. 10B, the passive element substrate 10 is installed on an insulating layer 23 formed on a substrate 21. Also, a wiring part 22 covered with the insulating layer 23 is formed on the substrate 21. Also, a wiring part 24 made of a via plug connected to the wiring part 22 and pattern wiring connected to the via plug is formed in the insulating layer 23.

Then, in a step shown in FIG. 10C, an insulating layer (a build-up resin layer) 25 is formed so as to cover the passive element substrate 10 and the wiring part 24. Thereafter, a via hole 25C reaching the wiring part 24, a via hole 25A reaching the electrode pad 13A and a via hole 25B reaching the electrode pad 15A are respectively formed by, for example, a laser with respect to the insulating layer 25.

Then, in a step shown in FIG. 10D, a wiring part 26 made of a via plug formed in the via hole 25A and pattern wiring connected to the via plug, a wiring part 27 made of a via plug formed in the via hole 25B and pattern wiring connected to the via plug, and a wiring part 28 made of a via plug formed in the via hole 25C and pattern wiring connected to the via plug are respectively formed by, for example, a semi-additive method.

In this manner, the mounting substrate into which the passive element (for example, a capacitor) is built can be formed.

[Patent Reference 1] Japanese Patent Unexamined Publication No. 7-30258

[Patent Reference 2] Japanese Patent Unexamined Publication No. 8-181453

[Patent Reference 3] Japanese Patent Unexamined Publication No. 2005-72311

[Patent Reference 4] Japanese Patent Unexamined Publication No. 2005-191266

However, the related-art mounting substrate into which the passive element such as the capacitor is built had a problem that it is difficult to adjust (tune) characteristics of the passive element.

For example, in the case of a passive element built-in type substrate, the built-in passive element may be affected by resistance, parasitic capacitance or parasitic induction, etc. generated by installation etc. of wiring etc. connected. As a result of this, there were cases where the intended characteristics cannot be obtained when the passive element is connected to a semiconductor chip. In this case, when the passive element is exposed to the surface, there are cases where the characteristics can be adjusted by, for example, laser trimming, but when the passive element is built in, it becomes difficult to make these adjustments.

Also, in the passive element built-in type mounting substrate, it is necessary to route the wiring complicatedly and it is difficult to previously predict the characteristics as compared with wiring of a surface mounting type. As a result of this, in some cases, the need for a repeat of design, prototyping and evaluation in order to manufacture the final product arises.

For example, in Patent Reference 1 (Japanese Patent Unexamined Publication No. 7-30258) described above, a method for improving a yield of a mounting substrate by forming a plurality of electrodes of capacitors built into the mounting substrate and excluding the short-circuited capacitors (electrodes) from the connection is disclosed. However, in the method, a concrete method for adjusting characteristics of the capacitors is not disclosed.

Also, in Patent Reference 2 (Japanese Patent Unexamined Publication No. 8-181453) described above, a method for selecting a capacitor connected on the uppermost layer in a mounting substrate into which a plurality of capacitors with different electrode areas are built is disclosed. However, in the method, one electrode of the capacitor is common and connection of the capacitor is limited to parallel connection and a range of adjustment or freedom of design is not sufficient.

### SUMMARY

Embodiments of the present invention provide a mounting substrate, a manufacturing method of the mounting substrate, and a manufacturing method of a semiconductor device made by mounting a semiconductor chip on the mounting substrate.

Further, embodiments of the present invention provide a mounting substrate which has a passive element connected to a semiconductor chip and facilitates adjustment of characteristics of the passive element, a manufacturing method of the mounting substrate, and a manufacturing method of a semiconductor device made by mounting a semiconductor chip on the mounting substrate.

In the first viewpoint of one or more embodiments of the invention, a mounting substrate for mounting a semiconductor chip, comprises a plurality of passive elements which are connected to the semiconductor chip and are formed to be mutually electrically-independent, and a wiring part including a plurality of via plugs respectively independently connected to the plurality of passive elements and pattern wiring connected to the via plugs, wherein the wiring part is constructed so that a state of connection between the semiconductor chip and the plurality of passive elements can be changed by changing the pattern wiring.

The mounting substrate has a feature of facilitating adjustment of characteristics of the passive elements.

Also, when the passive element has a first electrode part and a second electrode part and the passive element includes a capacitor having a dielectric part formed between the first electrode part and the second electrode part or a resistor having a resistor part formed between the first electrode part and the second electrode part or an inductor having an inductor part formed between the first electrode part and the second electrode part and the via plugs are independently formed in correspondence with each of the first electrode part and the second electrode part, it becomes easy to adjust characteristics of the passive elements.

Also, when a via plug pair made by adjacently installing a first via plug connected to the first electrode part and a second via plug connected to the second electrode part is formed and also a plurality of the via plug pairs are formed so as to be arranged, it becomes easy to adjust a capacitor by the pattern wiring.

Also, in the second viewpoint of one or more embodiments of the invention, a manufacturing method of a mounting substrate which has a plurality of passive elements connected to a semiconductor chip and mounts the semiconductor chip, comprises a passive element installation step of installing the plurality of passive elements so as to be mutually independent, and a wiring part formation step of forming a wiring part including via plugs respectively independently connected to the plurality of passive elements and pattern wiring connected to the via plugs, wherein the wiring part is constructed so that a state of connection between the semiconductor chip and the plurality of passive elements can be changed by changing the pattern wiring.

According to the manufacturing method, a mounting substrate for facilitating adjustment of characteristics of the passive elements can be manufactured.

Also, in the case of further having a connection change step of changing a state of connection between the passive elements and the semiconductor chip by changing the pattern wiring after the wiring part formation step, it becomes easy to change characteristics of the mounting substrate.

Also, in the case of further having a measurement step of measuring characteristics of the passive elements after the wiring part formation step and performing the connection change step according to a result of the measurement step, detailed adjustment of characteristics of the mounting substrate can be made.

Also, when the passive element has a first electrode part and a second electrode part and the passive element includes a capacitor having a dielectric part formed between the first electrode part and the second electrode part or a resistor having a resistor part formed between the first electrode part and the second electrode part or an inductor having an inductor part formed between the first electrode part and the second electrode part and the via plugs are independently formed in correspondence with each of the first electrode part and the second electrode part, it becomes easy to adjust characteristics of the passive elements.

Also, in the third viewpoint of one or more embodiments of the invention, a semiconductor device which has a mounting substrate including passive elements connected to a semiconductor chip and the semiconductor chip mounted on the mounting substrate, comprises a passive element installation step of installing the plurality of passive elements so as to be mutually independent, a wiring part formation step of forming a wiring part including via plugs respectively independently connected to the plurality of passive elements and pattern wiring connected to the via plugs, a measurement step of measuring characteristics of the passive elements, and a connection step of connecting the passive elements to the semiconductor chip through the wiring part, wherein in the connection step, the passive elements are connected to the semiconductor chip according to a result of the measurement step.

According to the manufacturing method, a semiconductor device in which a predetermined characteristic is obtained by adjusting characteristics according to a result of the measurement step can be manufactured.

Also, when the connection step includes a step of changing the pattern wiring formed in the wiring part formation step according to a result of the measurement step, it becomes easy to adjust characteristics of the semiconductor device.

Also, when the passive element has a first electrode part and a second electrode part and the passive element includes a capacitor having a dielectric part formed between the first electrode part and the second electrode part or a resistor having a resistor part formed between the first electrode part and the second electrode part or an inductor having an inductor part formed between the first electrode part and the second electrode part and the via plugs are independently formed in correspondence with each of the first electrode part and the second electrode part, it becomes easy to adjust characteristics of the passive elements.

Various implementations may include one or more the following advantages. For example, a mounting substrate which has a passive element connected to a semiconductor chip and facilitates adjustment of characteristics of the passive element, a manufacturing method of the mounting substrate, and a manufacturing method of a semiconductor device made by mounting a semiconductor chip on the mounting substrate can be provided.

Other features and advantages may be apparent from the following detailed description, the accompanying drawings and the claims.

### BRIEF DESCRIPTION OF THE DRAWINGS

FIG. 1A is a diagram showing a manufacturing method of a mounting substrate (semiconductor device) according to a first embodiment (first).

FIG. 1B is a diagram showing a manufacturing method of the mounting substrate (semiconductor device) according to the first embodiment (second).

FIG. 1C is a diagram showing a manufacturing method of the mounting substrate (semiconductor device) according to the first embodiment (third).

FIG. 1D is a diagram showing a manufacturing method of the mounting substrate (semiconductor device) according to the first embodiment (fourth).

FIG. 2A is a diagram showing an example of a configuration of pattern wiring of a mounting substrate (first).

FIG. 2B is a diagram showing an example of a configuration of the pattern wiring of the mounting substrate (second).

FIG. 3A is a diagram showing an example of a configuration of the pattern wiring of the mounting substrate (third).

FIG. 3B is a diagram showing an example of a configuration of the pattern wiring of the mounting substrate (fourth).

FIG. 3C is a diagram showing an example of a configuration of the pattern wiring of the mounting substrate (fifth).

FIG. 3D is a diagram showing an example of a configuration of the pattern wiring of the mounting substrate (sixth).

FIG. 3E is a diagram showing an example of a configuration of the pattern wiring of the mounting substrate (seventh).

FIG. 3F is a diagram showing an example of a configuration of the pattern wiring of the mounting substrate (eighth).

FIG. 3G is a diagram showing an example of a configuration of the pattern wiring of the mounting substrate (ninth).

FIG. 3H is a diagram showing an example of a configuration of the pattern wiring of the mounting substrate (tenth).

FIG. 3I is a diagram showing an example of a configuration of the pattern wiring of the mounting substrate (eleventh).

FIG. 3J is a diagram showing an example of a configuration of the pattern wiring of the mounting substrate (twelfth).

FIG. 3K is a diagram showing an example of a configuration of the pattern wiring of the mounting substrate (thirteenth).

FIG. 3L is a diagram showing an example of a configuration of the pattern wiring of the mounting substrate (fourteenth).

FIG. 3M is a diagram showing an example of a configuration of the pattern wiring of the mounting substrate (fifteenth).

FIG. 3N is a diagram showing an example of a configuration of the pattern wiring of the mounting substrate (sixteenth).

FIG. 4A is a diagram showing a change method of pattern wiring of a mounting substrate (first).

FIG. 4B is a diagram showing a change method of the pattern wiring of the mounting substrate (second).

FIG. 5A is a diagram showing a manufacturing method of a mounting substrate (semiconductor device) according to a second embodiment (first).

FIG. 5B is a diagram showing a manufacturing method of the mounting substrate (semiconductor device) according to the second embodiment (second).

FIG. 5C is a diagram showing a manufacturing method of the mounting substrate (semiconductor device) according to the second embodiment (third).

FIG. 5D is a diagram showing a manufacturing method of the mounting substrate (semiconductor device) according to the second embodiment (fourth).

FIG. 5E is a diagram showing a manufacturing method of the mounting substrate (semiconductor device) according to the second embodiment (fifth).

FIG. 5F is a diagram showing a manufacturing method of the mounting substrate (semiconductor device) according to the second embodiment (sixth).

FIG. 5G is a diagram showing a manufacturing method of the mounting substrate (semiconductor device) according to the second embodiment (seventh).

FIG. 6A is a diagram showing a manufacturing method of a mounting substrate (semiconductor device) according to a third embodiment (first).

FIG. 6B is a diagram showing a manufacturing method of the mounting substrate (semiconductor device) according to the third embodiment (second).

FIG. 6C is a diagram showing a manufacturing method of the mounting substrate (semiconductor device) according to the third embodiment (third).

FIG. 6D is a diagram showing a manufacturing method of the mounting substrate (semiconductor device) according to the third embodiment (fourth).

FIG. 6E is a diagram showing a manufacturing method of the mounting substrate (semiconductor device) according to the third embodiment (fifth).

FIG. 6F is a diagram showing a manufacturing method of the mounting substrate (semiconductor device) according to the third embodiment (sixth).

FIG. 7A is a diagram showing a manufacturing method of a mounting substrate (semiconductor device) according to a fourth embodiment (first).

FIG. 7B is a diagram showing a manufacturing method of the mounting substrate (semiconductor device) according to the fourth embodiment (second).

FIG. 8 is a diagram showing a mounting substrate according to a fifth embodiment.

FIG. 9 is a diagram showing a mounting substrate according to a sixth embodiment.

FIG. 10A is a diagram showing a manufacturing method of a related-art mounting substrate (first).

FIG. 10B is a diagram showing a manufacturing method of the related-art mounting substrate (second).

FIG. 10C is a diagram showing a manufacturing method of the related-art mounting substrate (third).

FIG. 10D is a diagram showing a manufacturing method of the related-art mounting substrate (fourth).

### DETAILED DESCRIPTION

Next, embodiments of the invention will be described based on the drawings.

### FIRST EMBODIMENT

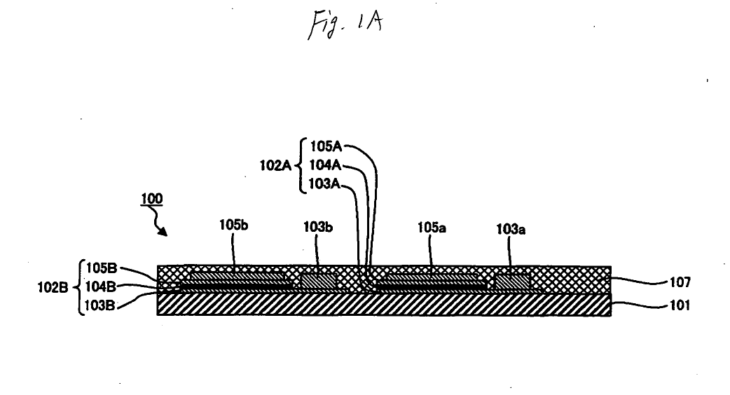

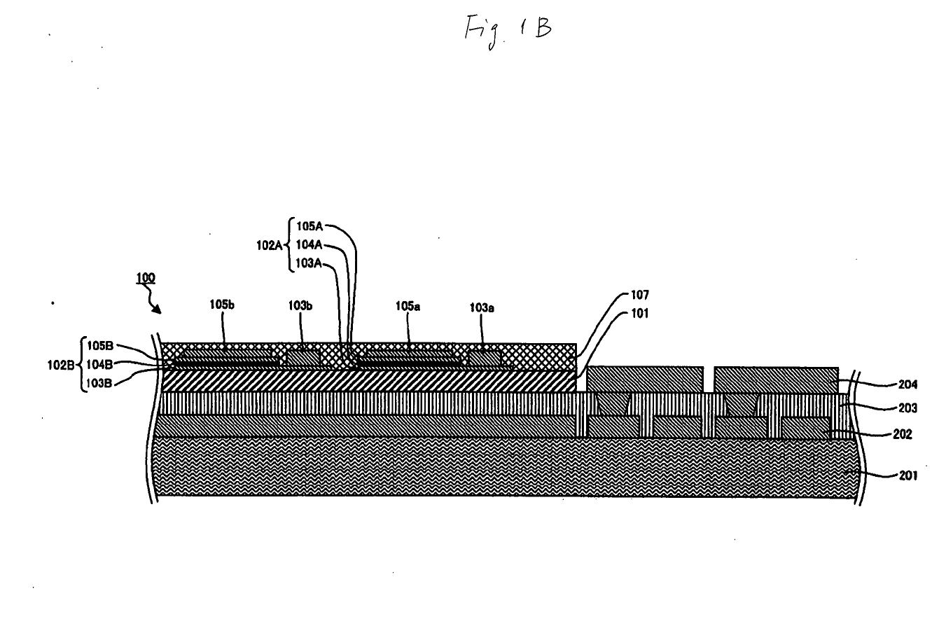

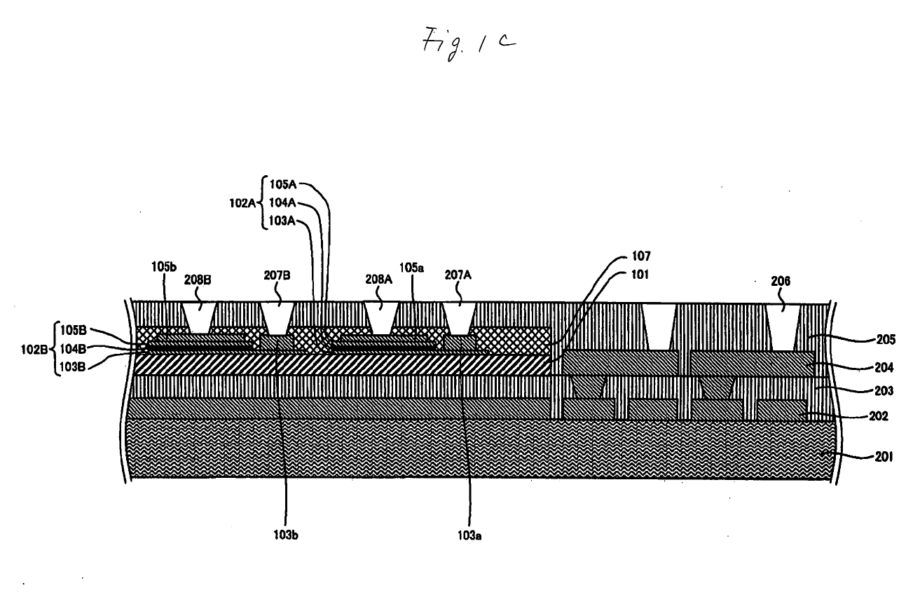

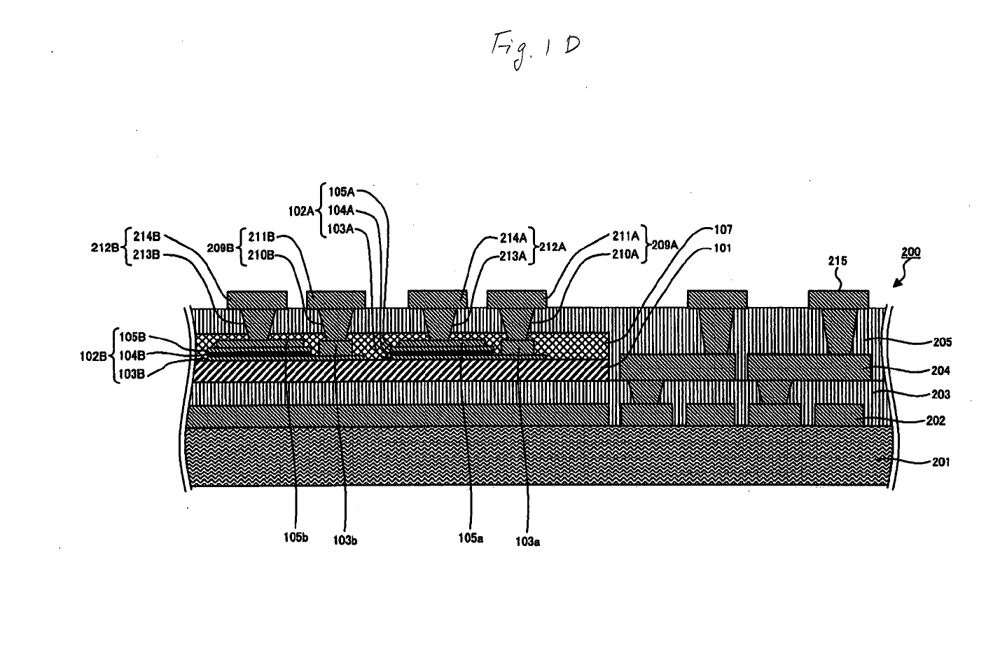

FIGS. 1A to 1D are diagrams showing a manufacturing method of a mounting substrate for mounting a semiconductor chip according to a first embodiment of the invention by following a procedure.

First, in a step shown in FIG. 1A, a plurality of passive elements (for example, capacitors) are independently formed on a substrate 101. For example, a capacitor (passive element) 102A made by forming a dielectric part 104A between a second electrode part 103A and a first electrode part 105A is formed on the substrate 101. In this case, an electrode pad 103a may be formed on the second electrode part 103A extending outside the dielectric part 104A and also an electrode pad 105a may be formed on the first electrode part 105A.

Similarly, a capacitor 102B made by forming a dielectric part 104B between a second electrode part 103B and a first electrode part 105B is formed on the substrate 101. In this case, an electrode pad 103b may be formed on the second electrode part 103B extending outside the dielectric part 104B and also an electrode pad 105b may be formed on the first electrode part 105B.

Also, illustration is omitted in the present drawing, but multiple capacitors (passive elements) may be constructed so as to be further formed in addition to the capacitors 102A, 102B. In this case, the formed capacitors (passive elements) are constructed so as to be independently formed mutually respectively. Then, an insulating layer 107 is formed so as to cover the capacitors 102A, 102B and a passive element substrate 100 made by installing the capacitors 102A, 102B is formed.

Next, in a step shown in FIG. 1B, the passive element substrate 100 is installed on an insulating layer 203 formed on a substrate 201. A wiring part 202 made of pattern wiring covered with the insulating layer 203 is formed on the substrate 201. Also, a wiring part 204 made of a via plug connected to the wiring part 202 and pattern wiring connected to the via plug is formed in the insulating layer 203. The passive element substrate 100 is installed on the insulating layer 203 so as to be opposed to the wiring part 202 through the insulating layer 203 and also be adjacent to the wiring part 204.

Then, in a step shown in FIG. 1C, an insulating layer (a build-up resin layer) 205 is formed so as to cover the passive element substrate 100 and the wiring part 204. After the insulating layer 205 is formed, a via hole 206 reaching the wiring part 204 and via holes 207A, 208A, 207B, 208B respectively reaching the electrode pads 103a, 105a, 103b, 105b are formed by, for example, a laser with respect to the insulating layer 205.

Then, in a step shown in FIG. 1D, a wiring part 215 made of a via plug formed in the via hole 206 and pattern wiring connected to the via plug is formed by, for example, a semi-additive method.

Also, a wiring part 209A made of a via plug 210A formed in the via hole 207A and pattern wiring 211A connected to the via plug 210A, and a wiring part 212A made of a via plug 213A formed in the via hole 208A and pattern wiring 214A connected to the via plug 213A are respectively formed.

Similarly, a wiring part 209B made of a via plug 210B formed in the via hole 207B and pattern wiring 211B connected to the via plug 210B, and a wiring part 212B made of a via plug 213B formed in the via hole 208B and pattern wiring 214B connected to the via plug 213B are respectively formed.

In this manner, amounting substrate 200 into which a plurality of mutually independent passive elements (for example, the capacitors 102A, 102B) are built can be formed. Thereafter, a semiconductor chip can be mounted so as to be connected to, for example, the wiring parts 215, 209A, 209B, 212A, 212B.

In the mounting substrate 200, a plurality of mutually independent passive elements (capacitors 102A, 102B) are built into so as to be embedded in the insulating layer 205. Further, the via plugs (via plugs 210A, 213A, 210B, 213B) independently connected to the respective passive elements (capacitors 102A, 102B) are formed in the insulating layer 205. As a result of this, a state of connection between the mounted semiconductor chip and the plurality of passive elements (for example, the capacitors 102A, 102B) can be adjusted easily by variously forming the pattern wirings 211A, 214A, 211B, 214B connected to these via plugs formed on the insulating layer 205. As a result of this, the mounting substrate according to the embodiment described above has a feature in which characteristics of the passive elements connected to the semiconductor chip can be adjusted easily even after the passive elements are embedded.

A related-art passive element built-in type mounting substrate had a problem that it is difficult to adjust characteristics of a passive element when the passive element is embedded in an insulating layer. Particularly, it is difficult to accurately calculate an influence of electrical characteristics of a wiring structure for making connection between the passive element and a semiconductor chip, so that there were cases where the need for a repeat of prototyping of the mounting substrate arises.

On the other hand, the mounting substrate according to the embodiment is constructed so that a connection state of a plurality of independent passive elements can be adjusted easily by variously forming the pattern wirings formed on the insulating layer in which the plurality of passive elements are embedded. As a result of this, characteristics of the passive elements functioning by being substantially connected to the semiconductor chip can be adjusted variously as necessary.

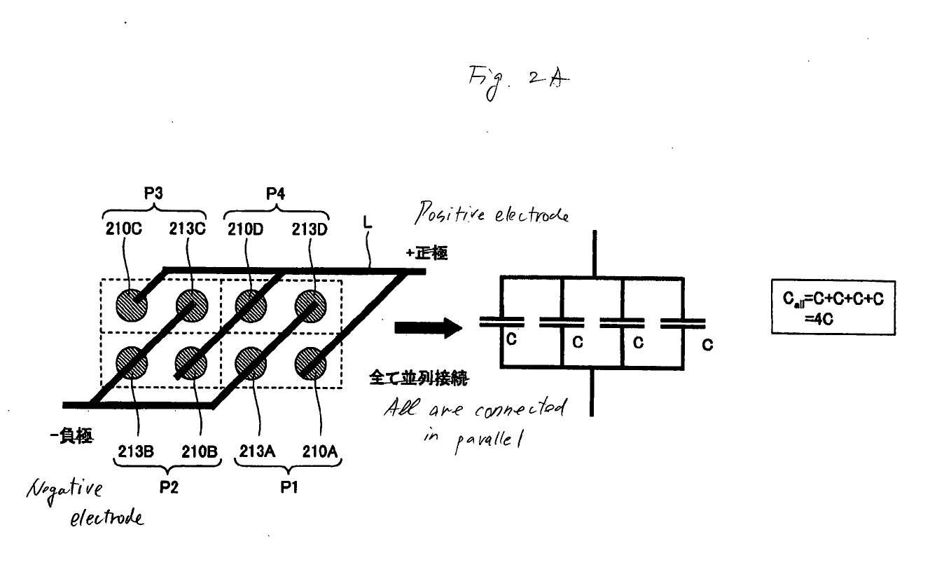

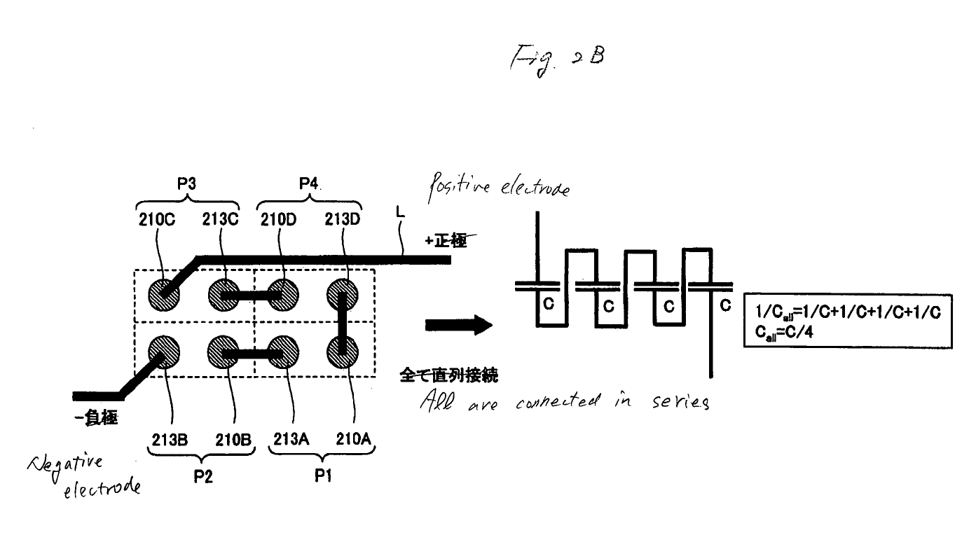

FIGS. 2A and 2B are plan diagrams showing one example of a configuration of pattern wiring in the mounting substrate 200. However, in the diagrams, the same reference numerals are assigned to the parts described above and the description is omitted. Also, via plugs 210C, 213C, 210D, 213D whose illustration is omitted in FIG. 1D are described in FIGS. 2A and 2B. The via plugs 210C, 213C are respectively connected to a second electrode part and a first electrode part of a capacitor whose illustration is omitted in FIG. 1D and similarly, the via plugs 210D, 213D are respectively connected to a second electrode part and a first electrode part of a capacitor whose illustration is omitted in FIG. 1D. That is, in the mounting substrate 200, for example, four capacitors are formed and are formed on the insulating layer 205. Characteristics of a passive element connected to a semiconductor chip can be adjusted by a shape of pattern wiring connected to these via plugs.

Referring to FIG. 2A, in the case shown in the present diagram, via plugs 210A, 210B, 210C, 210D are connected to a positive electrode and similarly via plugs 213A, 213B, 213C, 213D are connected to a negative electrode by pattern wiring L (corresponding to the pattern wiring 211A, 211B, 214A, 214B, etc. of FIG. 1D). That is, in the case shown in the present diagram, all the capacitors are connected in parallel. In this case, when capacitance of one capacitor is set at C, capacitance of capacitors combined by the connected capacitors becomes 4C.

Also, referring to FIG. 2B, in the case shown in the present diagram, all the capacitors are connected in series by pattern wiring L. In this case, when capacitance of one capacitor is set at C, combined capacitance becomes C/4.

Also, in the mounting substrate 200, the via plugs 210A, 210B, 210C, 210D, 213A, 213B, 213C, 213D are independently formed in correspondence with each of the first electrode part and the second electrode part of a capacitor (passive element), so that series connection or parallel connection of the capacitors (passive elements) or connections such as combinations of the series connection and the parallel connection can be made easily. As a result of that, a range of adjustment of capacitance of the capacitor increases and also a step of adjustment of the capacitor can be fined down.

Also, in the mounting substrate 200, a via plug pair P1 made by adjacently installing a via plug (for example, the via plug 210A) connected to the first electrode part and a via plug (for example, the via plug 213A) connected to the second electrode part of the capacitor is formed. Similarly, via plug pairs P2, P3, P4 made by respectively adjacently installing the via plugs (210B, 210C, 210D) connected to the first electrode part of the capacitor and the via plugs (213B, 213C, 213D) connected to the second electrode part of the capacitor are respectively formed. Further, the via plug pairs P1 to P4 are formed so as to be arranged.

As a result of this, it becomes easier to make series connection or parallel connection of the capacitors (passive elements) or connections such as combinations of the series connection and the parallel connection.

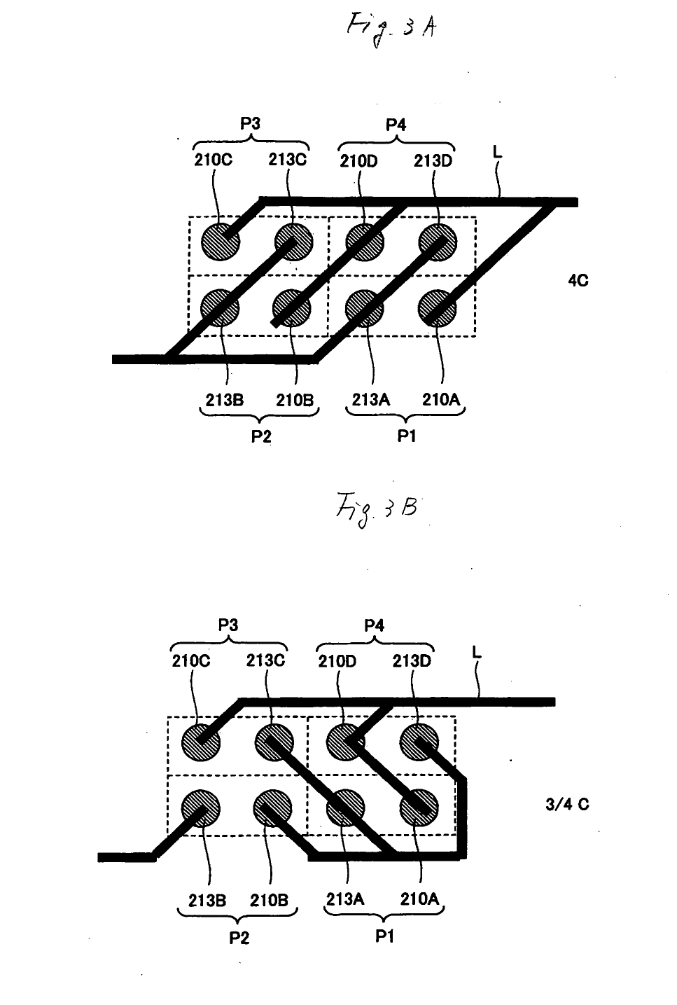

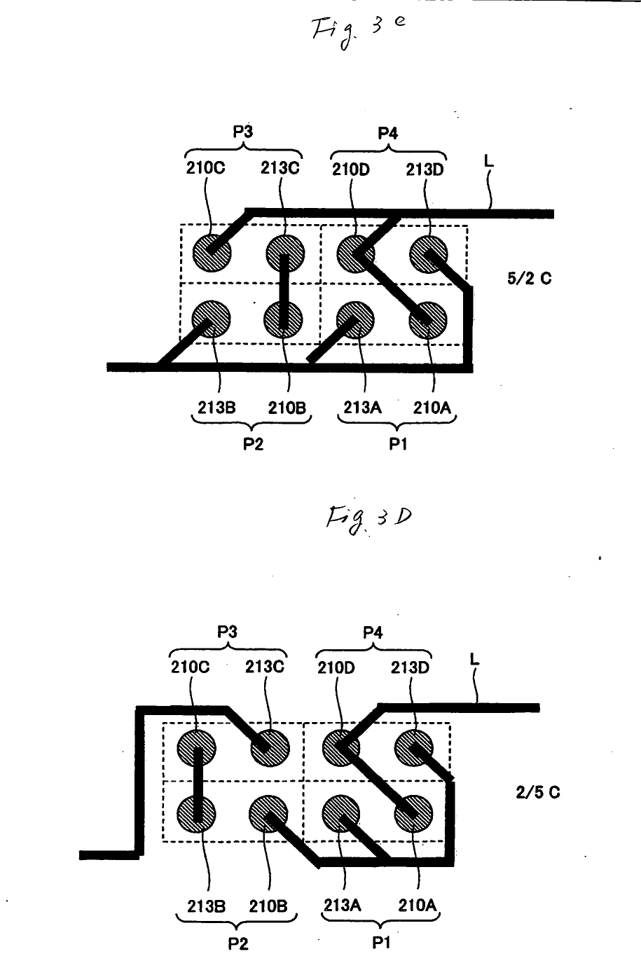

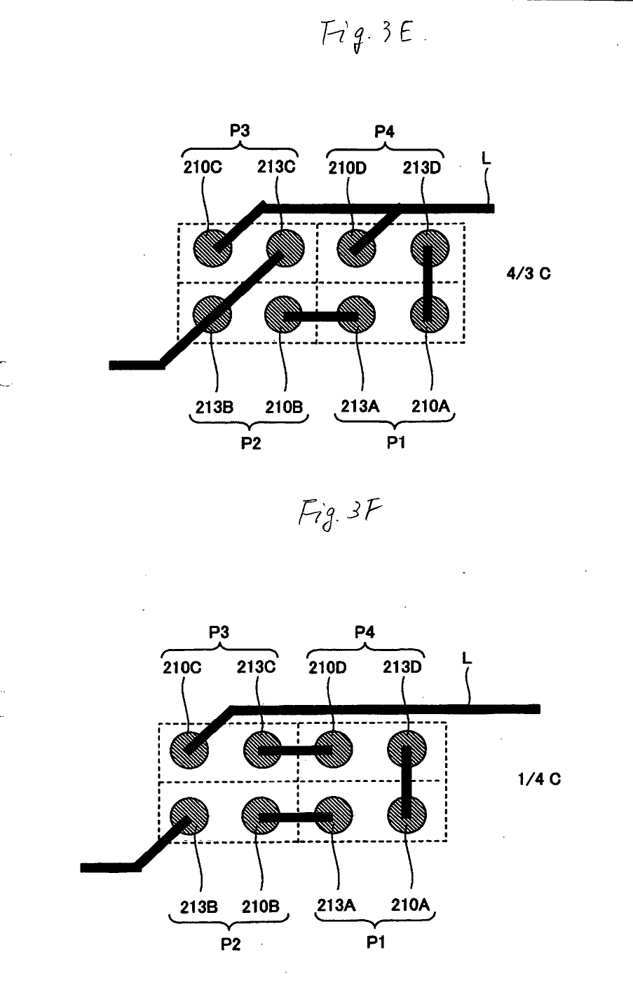

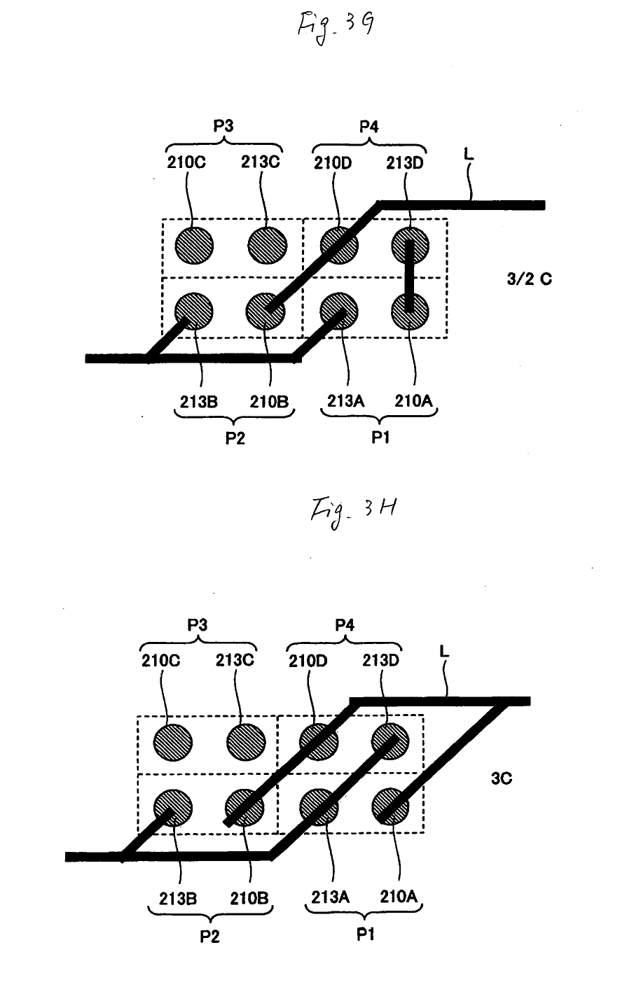

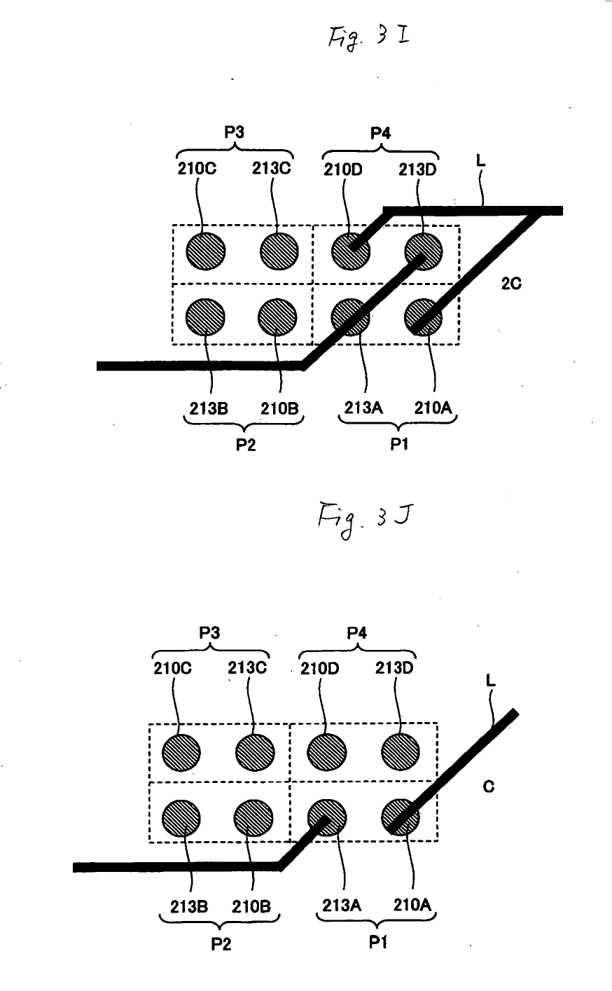

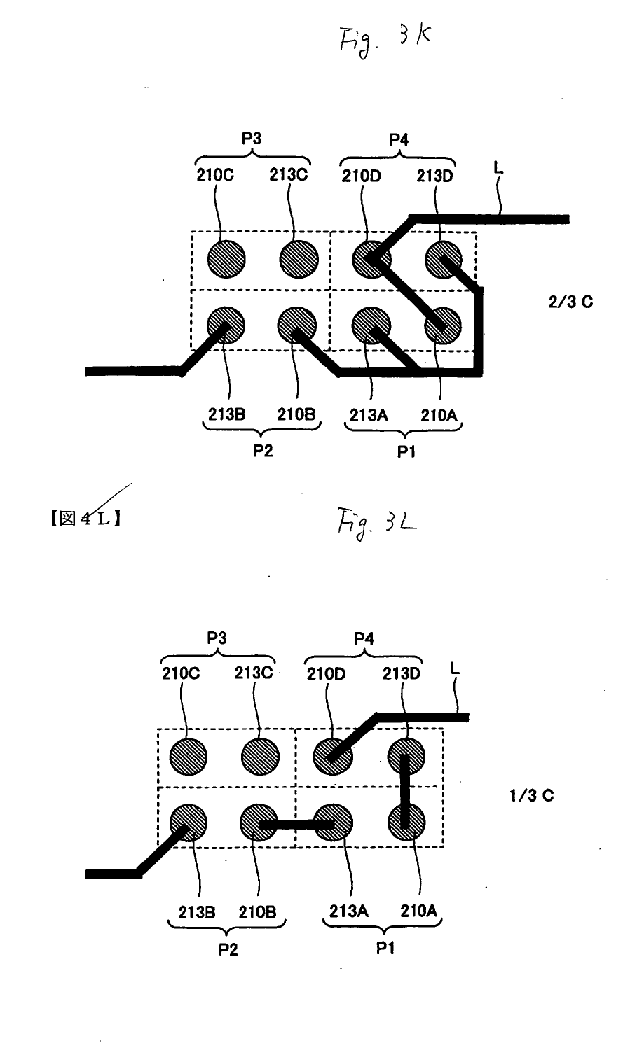

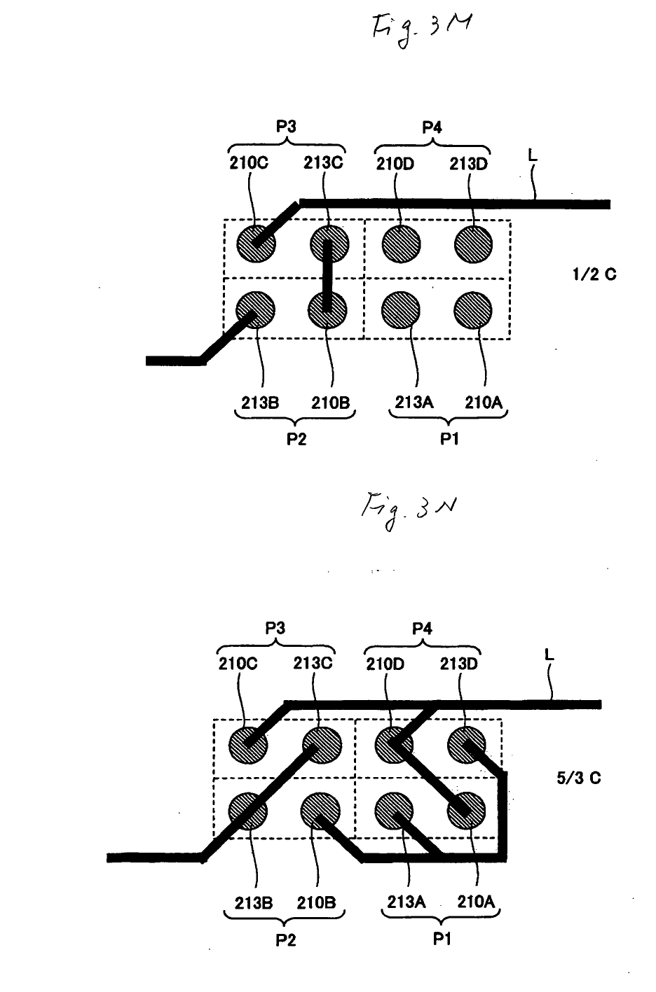

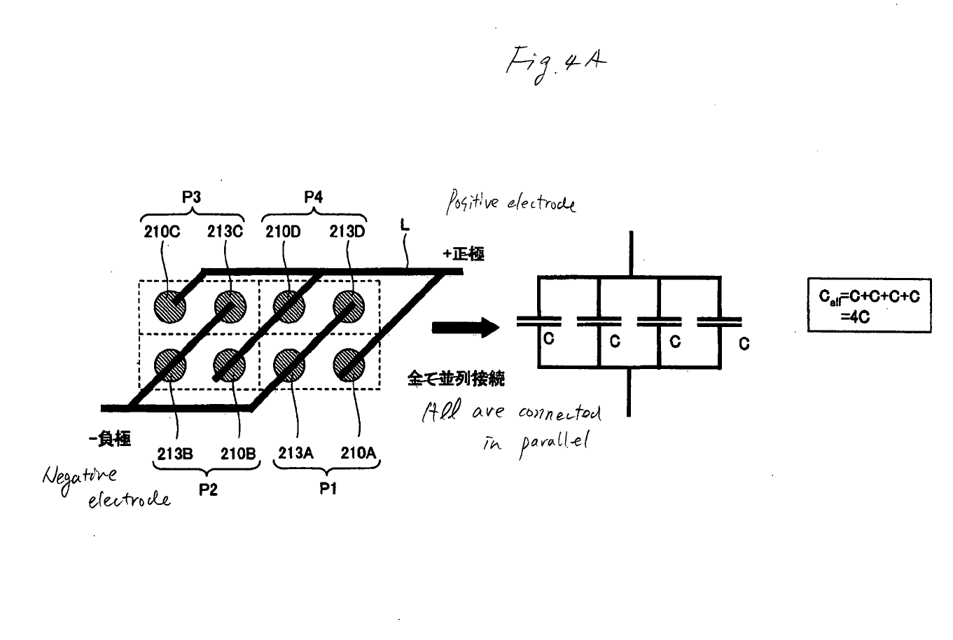

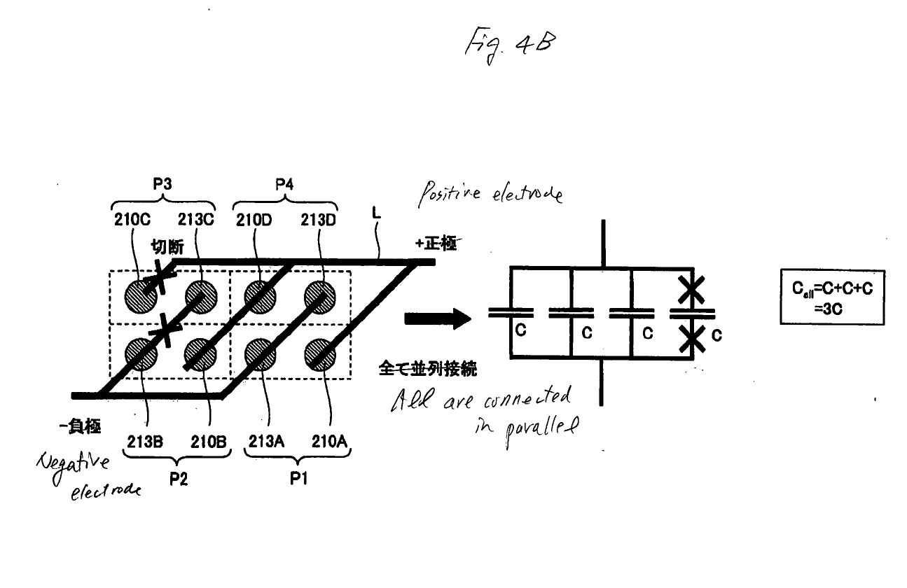

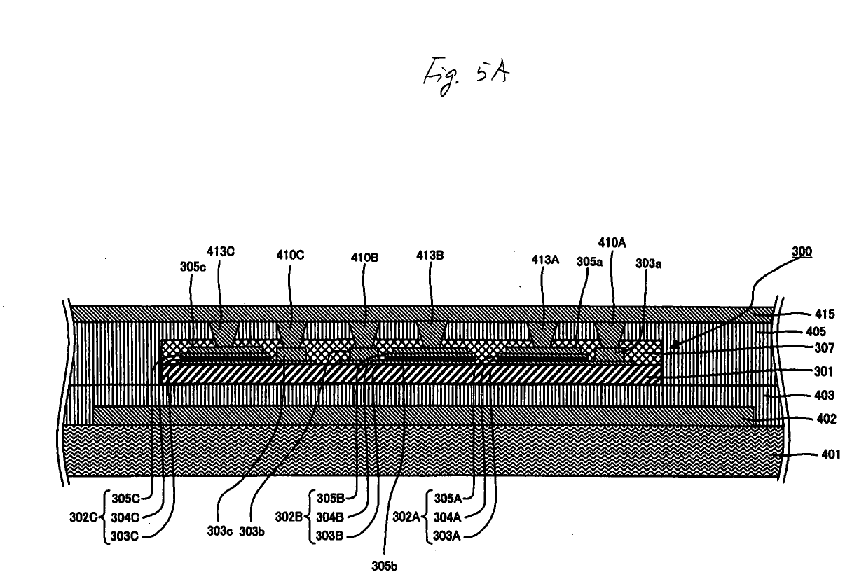

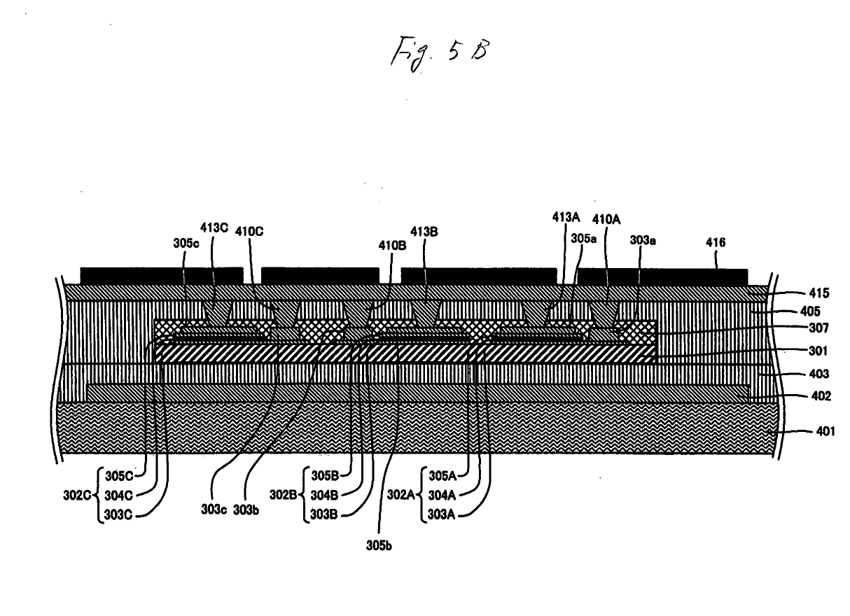

For example, FIGS. 3A to 3N are diagrams showing examples of configurations of pattern wiring of the mounting substrate 200. However, in the diagrams, the same reference numerals are assigned to the parts described above and the description is omitted.

As shown in FIGS. 3A to 3N, in the mounting substrate 200, characteristics of passive elements (for example, capacitance of capacitors) connected to a semiconductor chip can easily be variously changed by variously forming pattern wiring connected to the via plugs. In this case, the capacitance of capacitors can be changed from C/4 (minimum) to 4C (maximum) in 14 ways.

Also, in the mounting substrate 200, it becomes easy to variously change characteristics of passive elements functioning by being substantially connected to a semiconductor chip as necessary by changing pattern wiring of the mounting substrate formed once.

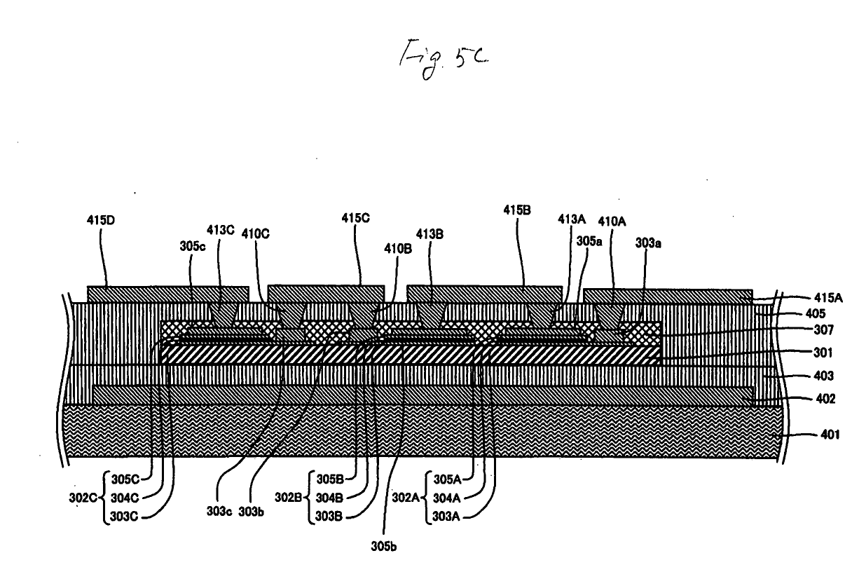

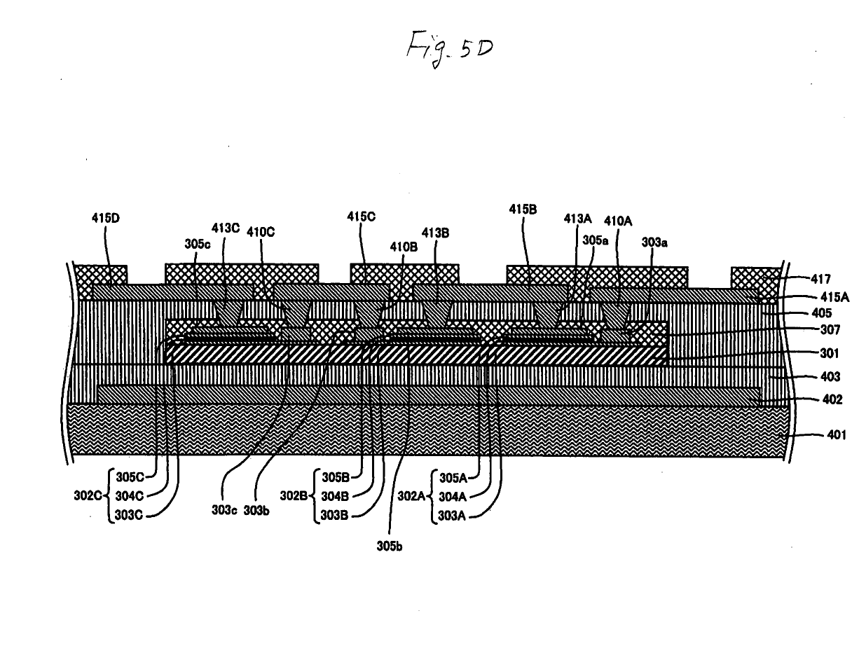

FIGS. 4A and 4B are diagrams schematically showing a change method of pattern wiring in the mounting substrate 200. However, in the diagrams, the same reference numerals are assigned to the parts described above and the detailed description is omitted.

First, referring to FIG. 4A, FIG. 4A corresponds to a state of FIG. 2A, and via plugs 210A, 210B, 210C, 210D are connected to a positive electrode and similarly via plugs 213A, 213B, 213C, 213D are connected to a negative electrode by pattern wiring L. That is, in the case shown in the present diagram, all the capacitors are connected in parallel, and capacitance of the capacitors combined by the connected capacitors becomes 4C.

Also, FIG. 4B is a diagram schematically showing a change in the pattern wiring and as shown in the present diagram, a change can be made so that one of the connected capacitors is isolated and is not connected by cutting a part of the pattern wiring L by, for example, a laser or an FIB. In the case shown in the present diagram, capacitance of the capacitors combined by the connected capacitors is changed to 3C.

Thus, in the mounting substrate according to the embodiment, even after pattern wiring is formed, the pattern wiring is exposed on an insulating layer, so that the pattern wiring is easily changed and characteristics of passive elements connected to a semiconductor chip can be easily changed (adjusted). Also, the change in the pattern wiring is not limited to the case of cutting the pattern wiring as described above and a change of connecting separated pattern wiring can also be made by, for example, conductive ink or solder paste.

Also, it is preferable to change (adjust) characteristics of passive elements connected to a semiconductor chip by the change of such pattern wiring in correspondence with measurement of the passive elements after the pattern wiring is formed.

Also, in the embodiment, the case of mainly the capacitor as the passive element has been described as an example, but the invention is not limited to this case. For example, a passive element (resistor) including a resistor part formed between the first electrode part 105A (105B) and the second electrode part 103A (103B) or a passive element (inductor) including an inductor part formed between the first electrode part 105A (105B) and the second electrode part 103A (103B) may be used instead of the capacitor 102A (102B).

Also, a passive element formed between the first electrode part 105A (105B) and the second electrode part 103A (103B) by variously combining a dielectric part, a resistor part, an inductor part, etc. as necessary may be used instead of the capacitor 102A (102B). With respect to structures of these passive elements, the same applies to the following mounting substrate (semiconductor device).

### SECOND EMBODIMENT

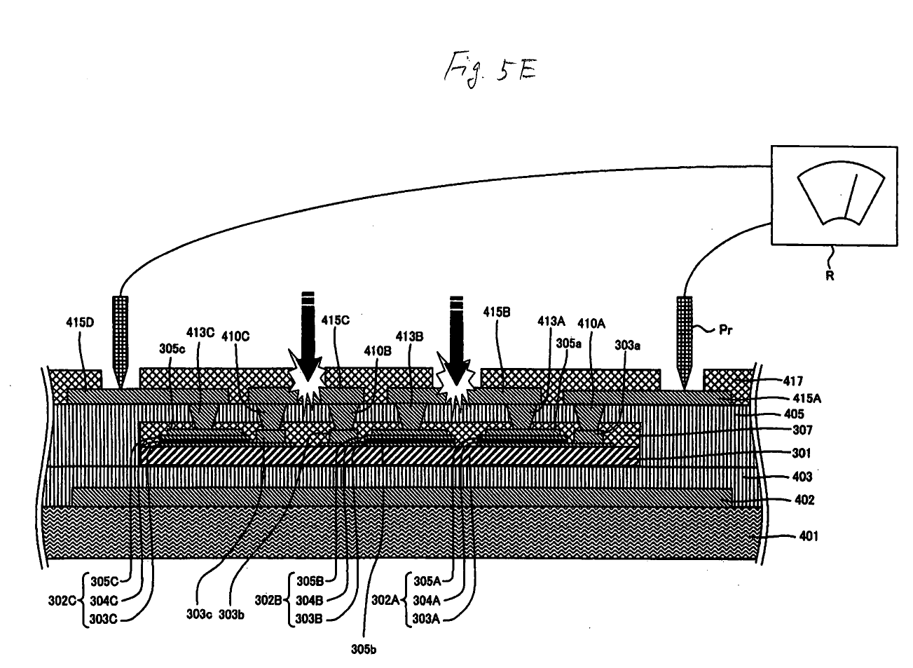

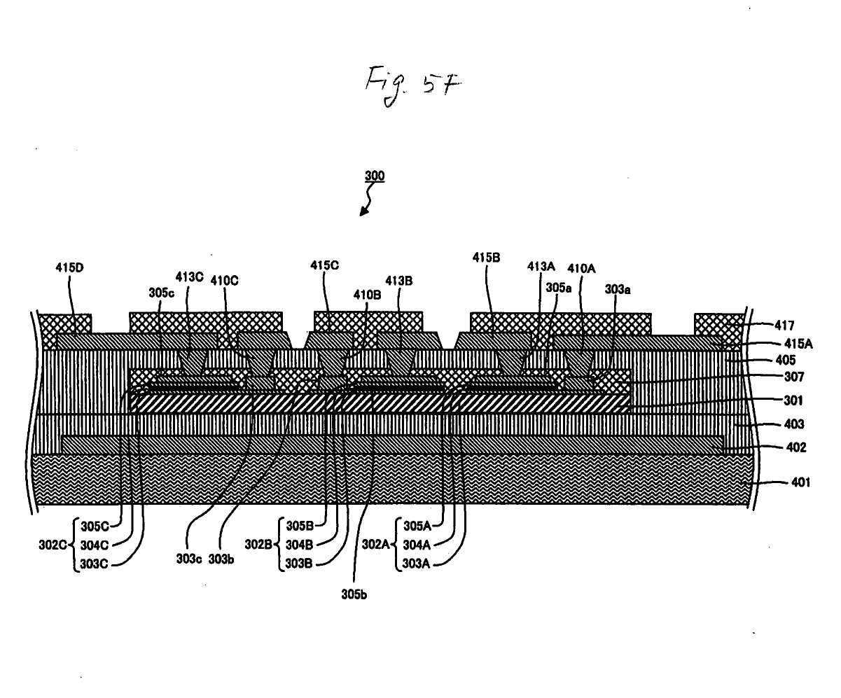

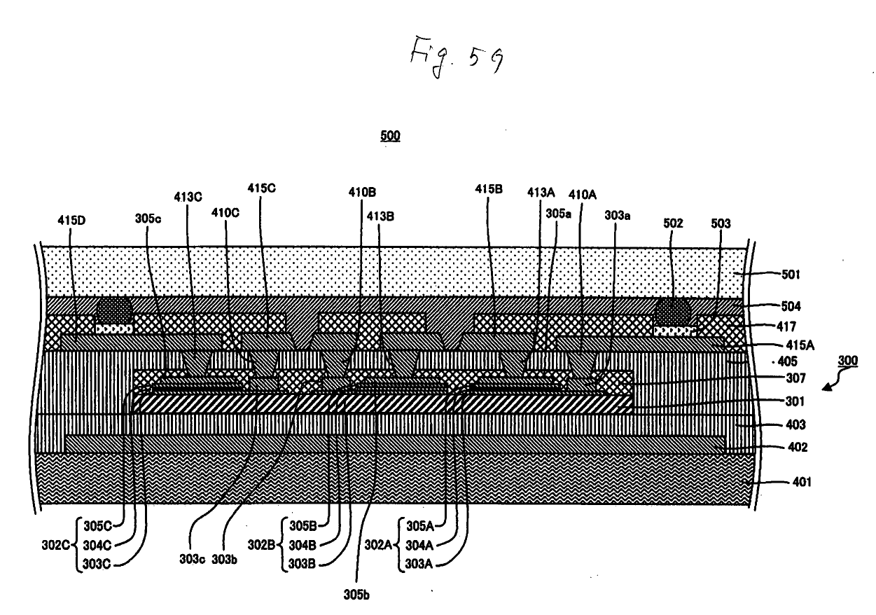

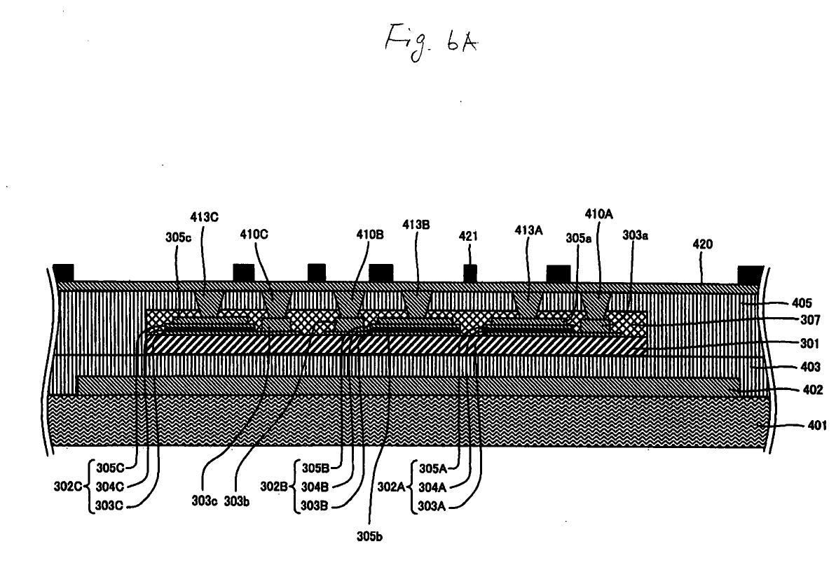

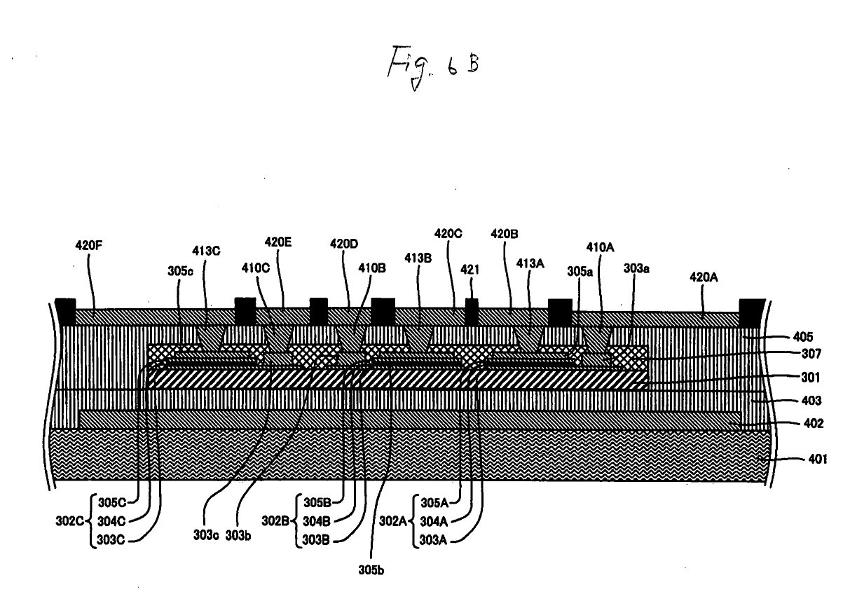

Next, a detailed example of a manufacturing method of the mounting substrate including a change in pattern wiring and measurement of the passive elements described above will be described based on FIGS. 5A to 5F. However, in the following diagrams, the same reference numerals are assigned to the parts described above and the description may be omitted.

First, a step shown in FIG. 5A corresponds to the steps of FIGS. 1C to 1D described above. In the case of the present embodiment, a substrate 401, a wiring part 402, an insulating layer 403 and an insulating layer 405 respectively correspond to the substrate 201, the wiring part 202, the insulating layer 203 and the insulating layer 205 of the first embodiment, respectively, and can be formed by a similar method.

Also, a passive element substrate 300 according to the embodiment corresponds to the passive element substrate 100 of the first embodiment. In this case, a substrate 301, an insulating layer 307, a capacitor 302A (a second electrode part 303A, a dielectric part 304A, a first electrode part 305A), electrode pads 303a, 305a, a capacitor 302B (a second electrode part 303B, a dielectric part 304B, a first electrode part 305B) and electrode pads 303b, 305b respectively correspond to the substrate 101, the insulating layer 107, the capacitor 102A (the second electrode part 103A, the dielectric part 104A, the first electrode part 105A), the electrode pads 103a, 105a, the capacitor 102B (the second electrode part 103B, the dielectric part 104B, the first electrode part 105B) and the electrode pads 103b, 105b of the first embodiment, and can be formed by a similar method.

In the case of the embodiment, a capacitor 302C (a second electrode part 303C, a dielectric part 304C, a first electrode part 305C) having a structure similar to that of the capacitors 302A, 302B and electrode pads 303c, 305c are further formed on the substrate 301.

In the present step, via plugs 410A, 413A, 410B, 413B, 410C, 413C are respectively formed in via holes reaching the electrode pads 303a, 305a, 303b, 305b, 303c, 305c formed in the insulating layers 405, 307 and further, a conductive layer 415 is formed on the via plugs by, for example, a plating method of Cu. In this case, the via plugs and the conductive layer are formed by electrolytic plating of Cu using a seed layer as a power feeding layer after the seed layer (not shown) is formed by electroless plating of Cu.

Next, in a step shown in FIG. 5B, a resist pattern 416 having openings is formed by patterning through exposure and development after a resist layer is formed on the conductive layer 415.

Then, in a step shown in FIG. 5C, the conductive layer 415 is patterned by etching the conductive layer 415 exposed from the resist pattern 416. As a result of that, pattern wiring 415A connected to the via plug 410A, pattern wiring 415B connected to the via plugs 413A, 413B, pattern wiring 415C connected to the via plugs 410B, 410C, and pattern wiring 415D connected to the via plug 413C are respectively formed. Thereafter, the resist pattern 416 is peeled,

Then, in a step shown in FIG. 5D, a solder resist layer 417 is formed on the insulating layer 405 so as to respectively expose parts of the pattern wirings 415A, 415B, 415C, 415D.

Then, in a step shown in FIG. 5E, a probe Pr connected to a measuring device R is brought into contact with the pattern wirings 415A, 415B, 415C, 415D, and built-in passive elements (capacitors 302A, 302B, 302C) are measured. Here, a state of connecting the passive elements (capacitors 302A, 302B, 302C) to a semiconductor chip is changed by changing connection of the pattern wirings 415A, 415B, 415C, 415D according to the measured result.

For example, in the present step, processing of cutting the pattern wirings 415B, 415C by a laser is performed. Here, characteristics of passive elements (for example, capacitance of capacitors) connected to the semiconductor chip are changed. Therefore, a mounting substrate 300 shown in FIG. 5F is formed.

Further, in a step shown in FIG. 5G, a semiconductor chip is mounted on the mounting substrate 300 and a semiconductor device made by mounting the semiconductor chip on the mounting substrate 300 can be formed.

In the step shown in FIG. 5G, a semiconductor chip 501 in which solder bumps 502 are formed is mounted so that, for example, the solder bumps 502 are electrically connected to the pattern wirings 415A, 415D. Also, a plated layer 503 for improving electrical connection may be formed between the solder bumps 502 and the pattern wirings 415A, 415D.

Also, an under fill 504 made of, for example, resin is inserted between the semiconductor chip 501 and the mounting substrate 300 after the semiconductor chip 501 is mounted. In this manner, a semiconductor device 500 can be formed.

In the semiconductor device 500, after passive elements (capacitors 302A to 302C) are embedded in an insulating layer and via plugs etc. for connecting the passive elements to a semiconductor chip are formed in the insulating layer, characteristics of the passive elements are actually measured and the characteristics of the passive elements are adjusted according to the measurement.

As a result of this, a semiconductor device with good characteristics in which the characteristics of the passive elements are adjusted according to a structure of connection between the passive elements to the semiconductor chip, for example, the formed via plugs can be formed.

Also, in the mounting substrate 300 (semiconductor device 500) described above, a wiring part for connecting the semiconductor chip to the passive elements has been formed by the so-called subtractive method, but the invention is not limited to this method. For example, the wiring part for connecting the semiconductor chip to the passive elements can also be formed by the so-called semi-additive method as shown in the following.

### THIRD EMBODIMENT

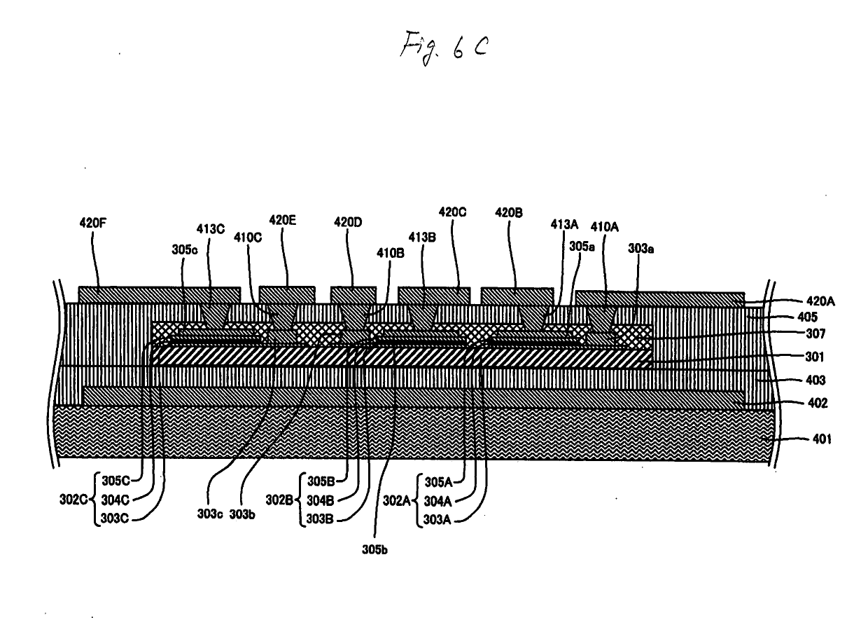

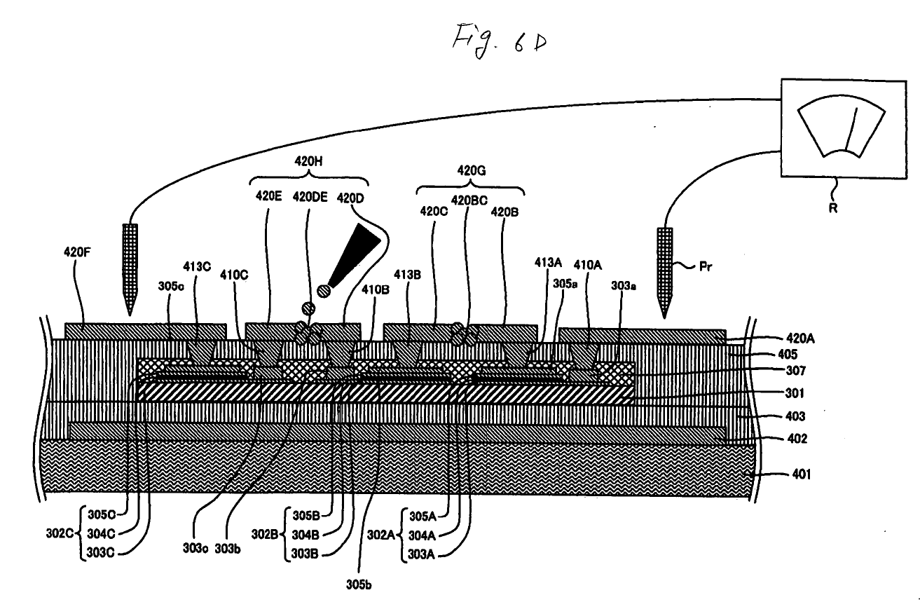

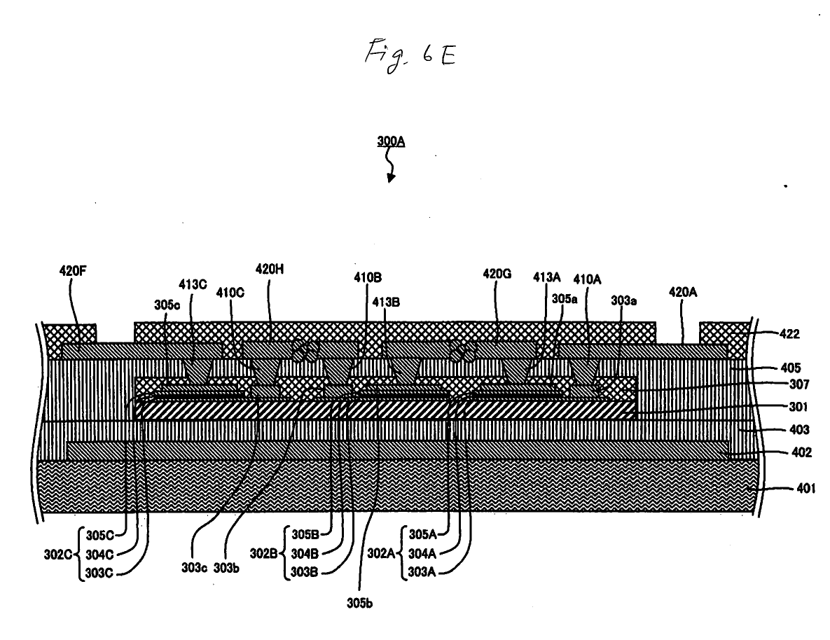

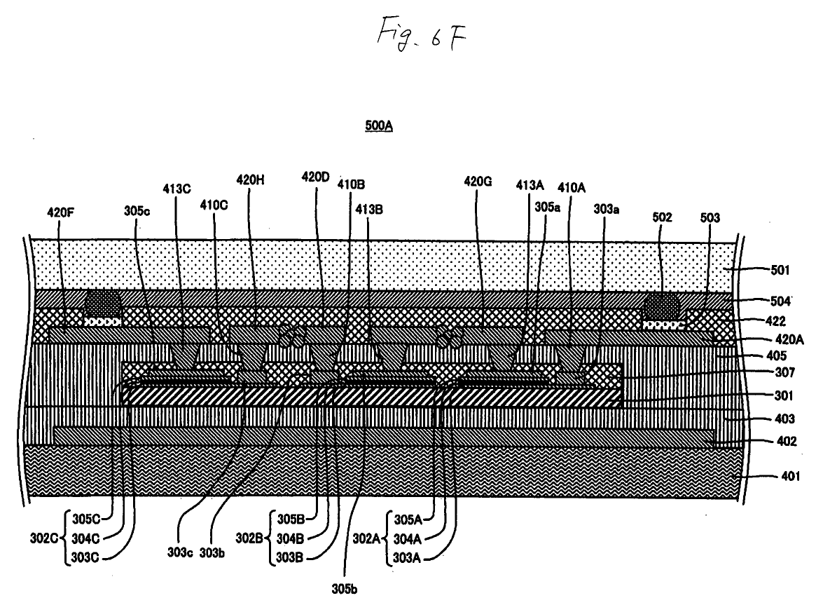

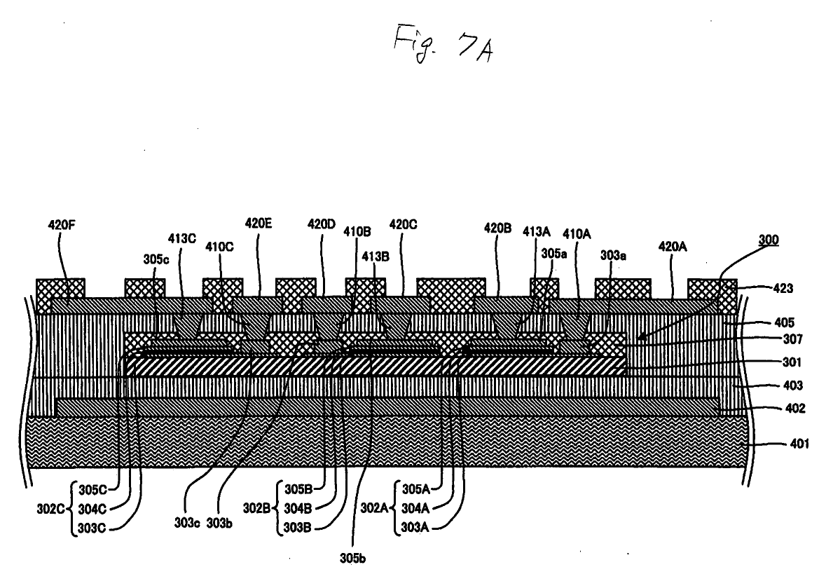

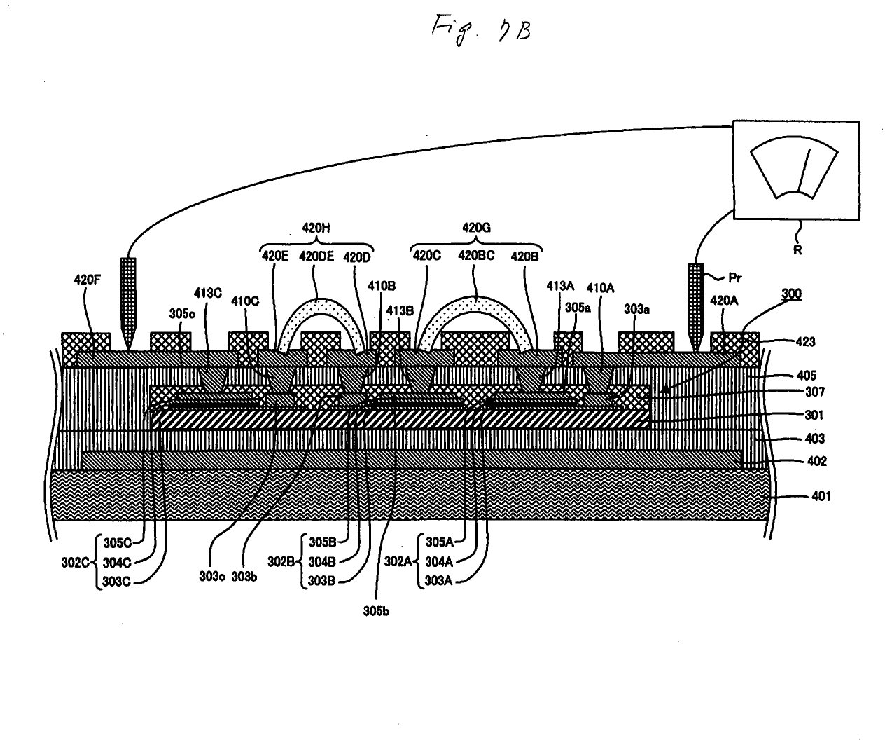

Next, a manufacturing method of a mounting substrate according to a third embodiment will be described based on FIGS. 6A to 6F. However, in the following diagrams, the same reference numerals are assigned to the parts described above and the description may be omitted.

First, a step shown in FIG. 6A corresponds to the step shown in FIG. 5A of the second embodiment described above. However, in the case of the present embodiment, via plugs 410A, 413A, 410B, 413B, 410C, 413C and a seed layer 420 on the via plugs (on the insulating layer 405) are first formed by electroless plating of Cu.

Next, a resist pattern 421 having openings is formed by patterning through exposure and development after a resist layer is formed on the seed layer 420.

Then, in a step shown in FIG. 6B, pattern wiring 420A connected to the via plug 410A, pattern wiring 420B connected to the via plug 413A, pattern wiring 420C connected to the via plug 413B, pattern wiring 420D connected to the via plug 410B, pattern wiring 420E connected to the via plug 410C and pattern wiring 420F connected to the via plug 413C are respectively formed on the seed layer 420 exposed from the resist pattern 421 by, for example, electrolytic plating of Cu.

Then, in a step shown in FIG. 6C, the resist pattern 421 is peeled and the pattern wirings 420A, 420B, 420C, 420D, 420E, 420F are separated.

Then, in a step shown in FIG. 6D, a probe Pr connected to a measuring device R is brought into contact with the pattern wirings 420A, 420B, 420C, 420D, 420E, 420F, and built-in passive elements (capacitors 302A, 302B, 302C) are measured. Here, a state of connecting the passive elements (capacitors 302A, 302B, 302C) to a semiconductor chip is changed by changing connection of the pattern wirings 420A, 420B, 420C, 420D, 420E, 420F according to the measured result.

For example, in the present step, processing of forming pattern wiring 420G by making connection between the pattern wiring 420B and the pattern wiring 420C by a connection line 420BC such as conductive ink or solder paste is performed. In like manner, processing of forming pattern wiring 420H by making connection between the pattern wiring 420D and the pattern wiring 420E by a connection line 420DE is performed. Here, characteristics of passive elements (for example, capacitance of capacitors) connected to the semiconductor chip are changed.

Then, in a step shown in FIG. 6E, a solder resist layer 422 is formed so as to respectively expose parts of the pattern wirings 420A, 420F and cover the pattern wirings 420G, 420H and the insulating layer 405. In this manner, a mounting substrate 300A is formed.

Further, in a step shown in FIG. 6F, a semiconductor chip 501 is mounted on the mounting substrate 300A and a semiconductor device 500A made by mounting the semiconductor chip on the mounting substrate 300A can be formed in a manner similar to the step shown in FIG. 5G. In this case, the semiconductor chip 501 is mounted so that the solder bumps 502 are electrically connected to the pattern wirings 420A, 420F. Also, a plated layer 503 for improving electrical connection may be formed between the solder bumps 502 and the pattern wirings 420A, 420F.

Also, an under fill 504 made of, for example, resin is inserted between the semiconductor chip 501 and the mounting substrate 300A after the semiconductor chip 501 is mounted. In this manner, the semiconductor device 500A can be formed.

Various methods such as a subtractive method or a semi-additive method can be used as a method for forming a wiring part thus. Also, when connection of pattern wiring is changed, various changes such as a change of cutting the pattern wiring or a change of connecting the pattern wiring can be added as necessary.

### FOURTH EMBODIMENT

Also, when a change of connecting pattern wiring is made, the change may be made by, for example, wire bonding as shown in the following.

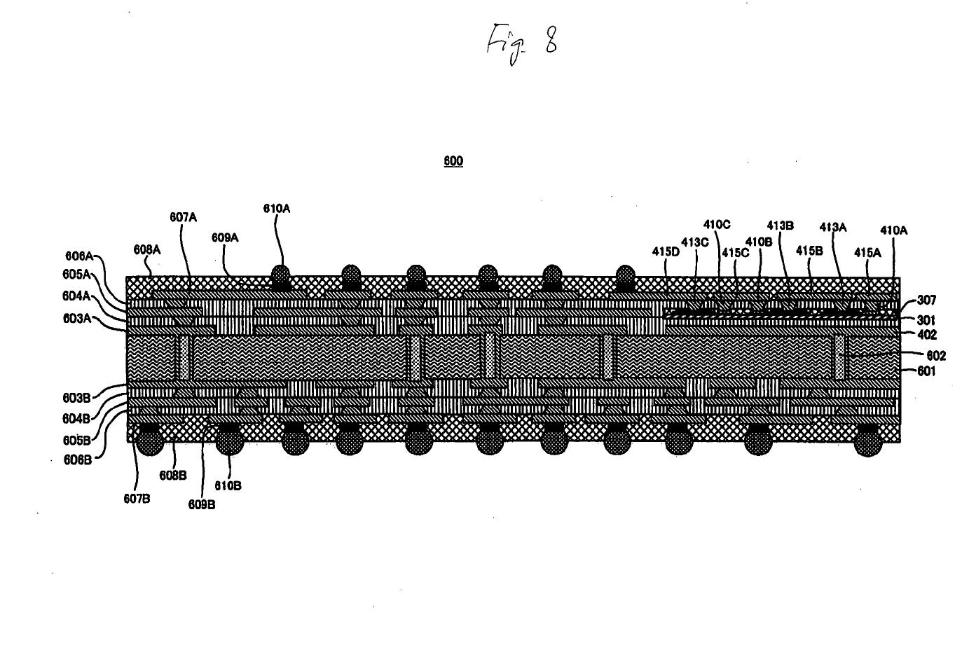

FIGS. 7A to 7B are diagrams showing a manufacturing method of a mounting substrate according to a fourth embodiment. However, in the following diagrams, the same reference numerals are assigned to the parts described above and the description is omitted.

First, the steps shown in FIGS. 6A to 6C of the third embodiment are performed. Next, in a step shown in FIG. 7A, a solder resist layer 423 is formed on the insulating layer 405 so as to respectively expose parts of the pattern wirings 420A, 420B, 420C, 420D, 420E, 420F.

Then, in a step shown in FIG. 7B, a probe Pr connected to a measuring device R is brought into contact with the pattern .wirings 420A, 420B, 420C, 420D, 420E, 420F, and built-in passive elements (capacitors 302A, 302B, 302C) are measured. Here, a state of connecting the passive elements (capacitors 302A, 302B, 302C) to a semiconductor chip is changed by changing connection of the pattern wirings 420A, 420B, 420C, 420D, 420E, 420F according to the measured result.

For example, in the present step, processing of forming pattern wiring 420G by making connection between the pattern wiring 420B and the pattern wiring 420C by a connection line 420BC made of a wire is performed. In like manner, processing of forming pattern wiring 420H by making connection between the pattern wiring 420D and the pattern wiring 420E by a connection line 420DE made of a wire is performed. Here, characteristics of passive elements (for example, capacitance of capacitors) connected to the semiconductor chip are changed. The semiconductor chip can be mounted below in a manner similar to the embodiment described above.

### FIFTH EMBODIMENT

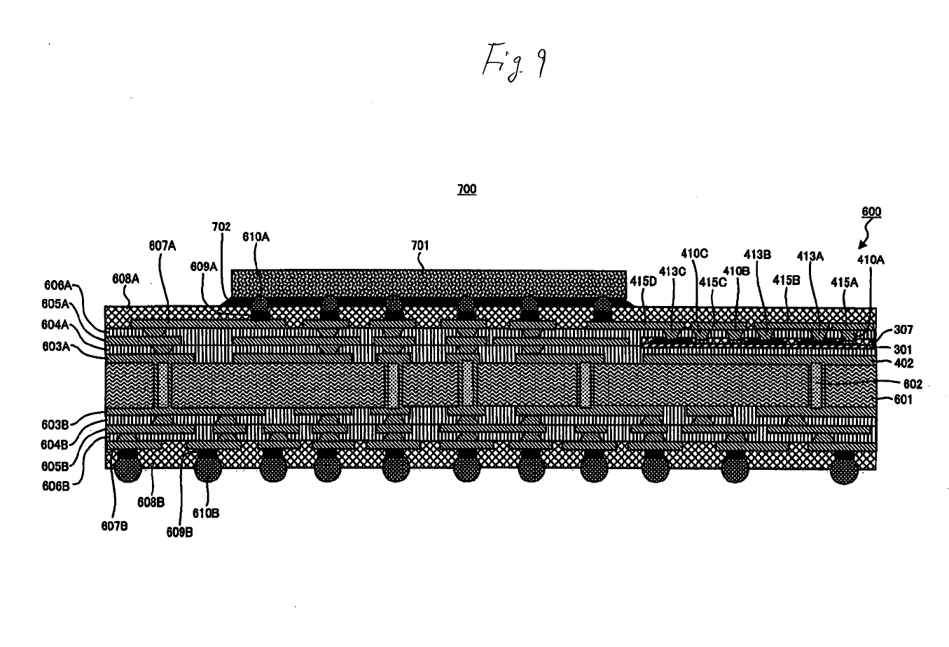

Also, FIG. 8 is a diagram showing a mounting substrate 600 for mounting a semiconductor chip according to a fifth embodiment of the invention. The mounting substrate 600 according to the present embodiment includes a structure of the mounting substrate shown in FIG. 5D and in the diagram, the same reference numerals are assigned to the parts described above and the description is omitted.

Referring to FIG. 8, the mounting substrate 600 has a structure in which a multilayer wiring structure is formed on both surfaces of the first side (side on which a semiconductor chip is mounted) and the second side of a core substrate 601. Via plugs 602 passing through the core substrate 601 are formed in the core substrate 601.

Also, a wiring part 603A is formed on the first side of the core substrate 601 and a wiring part 603B is formed on the second side of the core substrate 601. Also, insulating layers 604A, 606A made of build-up resin (epoxy resin) are sequentially laminated so as to cover the wiring part 603A, and wiring parts 605A, 607A made of via plugs and pattern wirings are respectively formed in the insulating layers 604A, 606A. Similarly, insulating layers 604B, 606B made of build-up resin (epoxy resin) are sequentially laminated so as to cover the wiring part 603B, and wiring parts 605B, 607B made of via plugs and pattern wirings are respectively formed in the insulating layers 604B, 606B.

Also, a solder resist layer 608A is formed on the insulating layer 606A so as to expose a part of the pattern wiring of the wiring part 607A, and solder balls 610A and connection layers 609A made of Au etc. are formed on the exposed wiring part 607A.

Similarly, a solder resist layer 608B is formed on the insulating layer 606B so as to expose a part of the pattern wiring of the wiring part 607B, and solder balls 610B and connection layers 609B made of Au etc. are formed on the exposed wiring part 607B.

In the structure described above, the structure shown in FIG. 5D is formed on the first side of the core substrate 601. In this case, the wiring part 402, the insulating layers 403, 405 and the solder resist layer 417 shown in FIG. 5D respectively correspond to the wiring part 603A, the insulating layers 604A, 606A and the solder resist layer 608A.

Also, the multilayer wiring structure is formed by the so-called build-up method, and the semi-additive method, the subtractive method, etc. described above can be applied.

Thus, the invention can be applied to the structure in which multilayer wiring is formed on both surfaces of the core substrate. Also, the invention is not limited to the structure using the core substrate, and can apparently be applied to various other structures.

### SIXTH EMBODIMENT

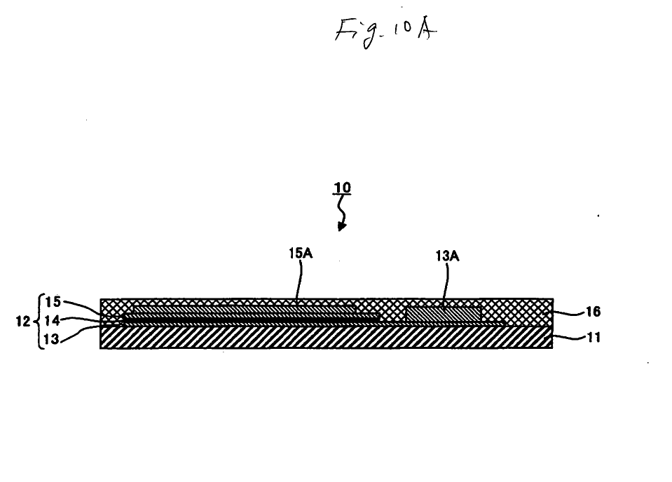

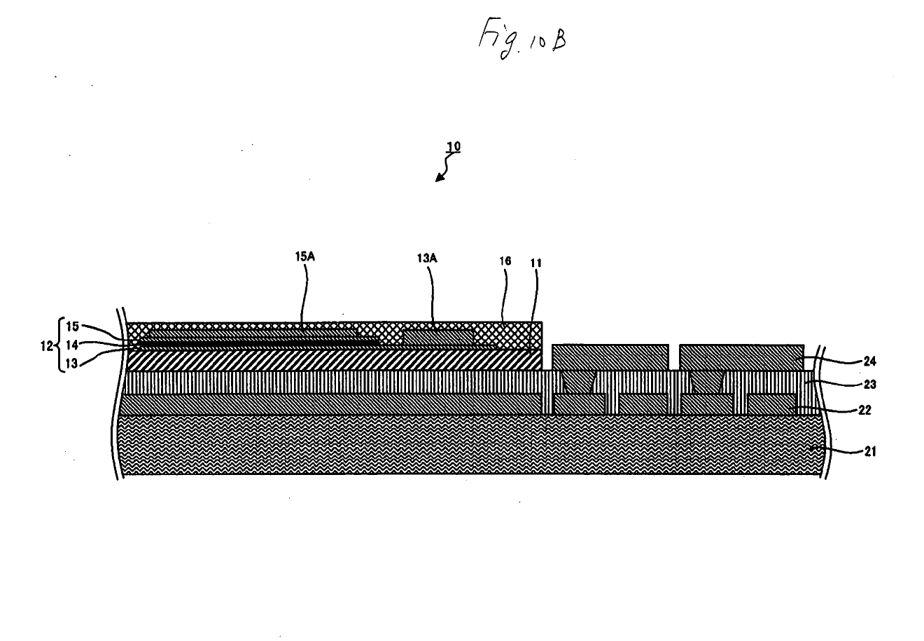

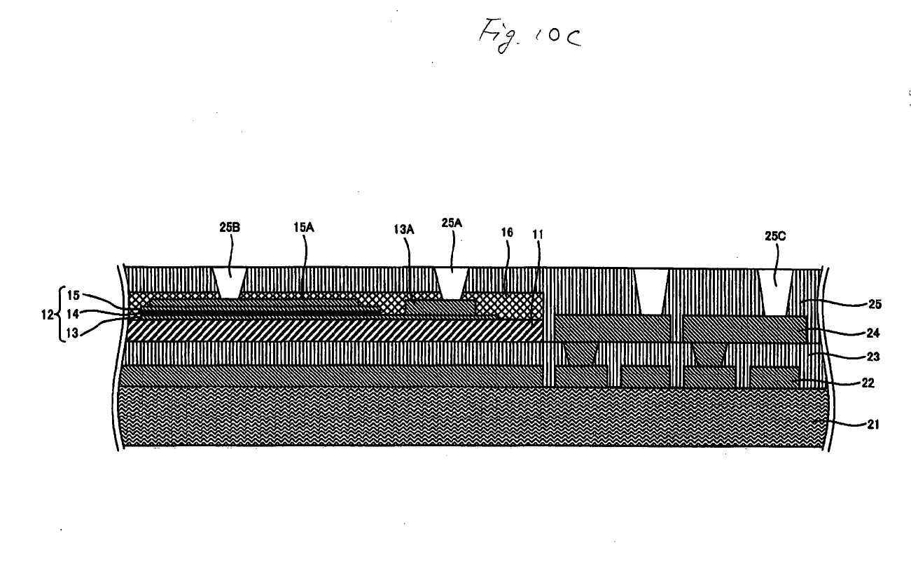

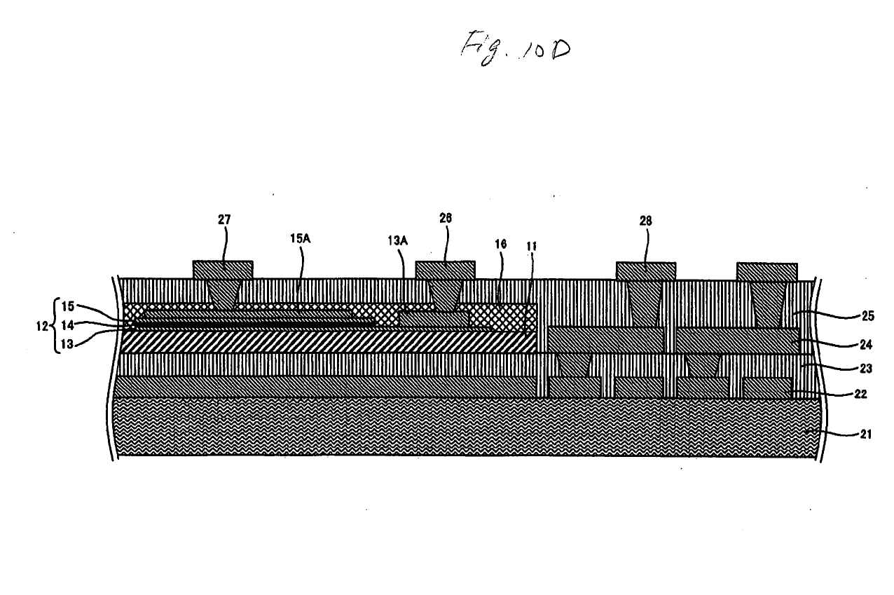

Also, FIG. 9 is a diagram showing a semiconductor device 700 according to a sixth embodiment of the invention. However, in the diagram, the same reference numerals are assigned to the parts described above and the description is omitted.

Referring to FIG. 9, the semiconductor device 700 according to the present embodiment has a structure made by mounting a semiconductor chip 701 on the mounting substrate 600. Also, an under fill 702 made of, for example, resin is inserted between the semiconductor chip 701 and the mounting substrate 600.

Thus, the invention is applied and a semiconductor device made by mounting a semiconductor chip on mounting substrates of various structures can be constructed.

The invention has been described above with reference to the preferred embodiments, but the invention is not limited to the specific embodiments, and various modifications and changes can be made within the gist described in the claims.

According to the invention, a mounting substrate which has a passive element connected to a semiconductor chip and facilitates adjustment of characteristics of the passive element, a manufacturing method of the mounting substrate, and a manufacturing method of a semiconductor device made by mounting a semiconductor chip on the mounting substrate can be provided.

What is claimed is:

1. A mounting substrate for mounting a semiconductor chip, comprising:
a plurality of passive elements which are connected to the semiconductor chip and are formed to be mutually electrically-independent; and
a wiring part including a plurality of via plugs respectively independently connected to the plurality of passive elements and pattern wiring connected to the via plugs,
wherein the wiring part is constructed so that a state of connection between the semiconductor chip and the plurality of passive elements can be changed by changing the pattern wiring.

2. A mounting substrate as claimed in claim 1, wherein the passive element has a first electrode part and a second electrode part, and the passive element includes a capacitor having a dielectric part formed between the first electrode part and the second electrode part or a resistor having a resistor part formed between the first electrode part and the second electrode part or an inductor having an inductor part formed between the first electrode part and the second electrode part, and the via plugs are independently formed in correspondence with each of the first electrode part and the second electrode part.

3. A mounting substrate as claimed in claim 2, wherein a via plug pair made by adjacently installing a first via plug connected to the first electrode part and a second via plug connected to the second electrode part is formed and also a plurality of the via plug pairs are formed so as to be arranged.

4. A manufacturing method of a mounting substrate which has a plurality of passive elements connected to a semiconductor chip and mounts the semiconductor chip, comprising:
a passive element installation step of installing the plurality of passive elements so as to be mutually electrically-independent; and
a wiring part formation step of forming a wiring part including via plugs respectively independently connected to the plurality of passive elements and pattern wiring connected to the via plugs,
wherein the wiring part is constructed so that a state of connection between the semiconductor chip and the plurality of passive elements can be changed by changing the pattern wiring.

5. A manufacturing method of a mounting substrate as claimed in claim 4, further comprising:
a connection change step of changing a state of connection between the passive elements and the semiconductor chip by changing the pattern wiring after the wiring part formation step.

6. A manufacturing method of a mounting substrate as claimed in claim 5, further comprising:
a measurement step of measuring characteristics of the passive elements after the wiring part formation step, wherein the connection change step is performed according to a result of the measurement step.

7. A manufacturing method of a mounting substrate as in claim 4, wherein the passive element has a first electrode part and a second electrode part, and the passive element includes a capacitor having a dielectric part formed between the first electrode part and the second electrode part or a resistor having a resistor part formed between the first electrode part and the second electrode part or an inductor having an inductor part formed between the first electrode part and the second electrode part, and the via plugs are independently formed in correspondence with each of the first electrode part and the second electrode part.

8. A manufacturing method of a semiconductor device which has a mounting substrate including passive elements connected to a semiconductor chip and the semiconductor chip mounted on the mounting substrate, comprising:
a passive element installation step of installing the plurality of passive elements so as to be mutually electrically-independent;
a wiring part formation step of forming a wiring part including via plugs respectively independently connected to the plurality of passive elements and pattern wiring connected to the via plugs;
a measurement step of measuring characteristics of the passive elements; and
a connection step of connecting the passive elements to the semiconductor chip through the wiring part,
wherein in the connection step, the passive elements are connected to the semiconductor chip according to a result of the measurement step.

9. A manufacturing method of a semiconductor device as claimed in claim 8, wherein the connection step includes a step of changing the pattern wiring formed in the wiring part formation step according to a result of the measurement step.

10. A manufacturing method of a semiconductor device as claimed in claim 8, wherein the passive element has a first electrode part and a second electrode part, and the passive element includes a capacitor having a dielectric part formed between the first electrode part and the second electrode part or a resistor having a resistor part formed between the first electrode part and the second electrode part or an inductor having an inductor part formed between the first electrode part and the second electrode part, and the via plugs are independently formed in correspondence with each of the first electrode part and the second electrode part.
